(19) United States
(12) Patent Application Publication
(10) Pub. No.: US 2025/0089420 A1
(43) Pub. Date: Mar. 13, 2025

(54) ARRAY SUBSTRATE AND ELECTRONIC APPARATUS

(71) Applicants: Hefei BOE Ruisheng Technology Co., Ltd., Hefei, Anhui (CN); BOE Technology Group Co., Ltd., Beijing (CN)

(72) Inventors: Hai TANG, Beijing (CN); Ping KANG, Beijing (CN); Chaoren LV, Beijing (CN); Kangli WANG, Beijing (CN); Liang GAO, Beijing (CN)

(21) Appl. No.: 18/028,299

(22) PCT Filed: May 27, 2022
(86) PCT No.: PCT/CN2022/095708

§ 371 Date: Mar. 24, 2023

(51) Int. Cl. H01L 33/62; H01L 25/16

(52) U.S. Cl. CPC H10H 20/857; H01L 25/167

(57) ABSTRACT

Provided are an array substrate and an electronic apparatus. The array substrate includes: a base substrate; a first conductive layer on the base substrate, where the first conductive layer includes a plurality of pads, each pad includes a first metal layer, a material of the first metal layer includes Cu, a content of the Cu is greater than or equal to 99%, and a thickness of the first metal layer is greater than 2 μm; and an electronic element disposed on a side of the first conductive layer facing away from the base substrate, where the electronic element includes an electronic element body and a plurality of pins disposed on a side of the electronic element body facing the base substrate, and the pins are connected with the pads.

### CROSS REFERENCE TO RELATED APPLICATIONS

The present disclosure is a National Stage of International Application No. PCT/CN2022/095708, filed May 27, 2022.

### FIELD

The present disclosure relates to the technical field of display, and particularly relates to an array substrate and an electronic apparatus.

### BACKGROUND

As the most popular technology and process in the electronic assembly industry, the surface mounted technology (SMT) is to place an electronic element having pins on a surface of a base substrate having pads and solder and assemble the element through reflow soldering or dip soldering.

### SUMMARY

Embodiments of the present disclosure provide an array substrate and an electronic apparatus. A solution is as follows.

In one aspect, an array substrate provided in an embodiment of the present disclosure includes:
a base substrate:
a first conductive layer, disposed on the base substrate, where the first conductive layer includes a plurality of pads, each of the plurality of pads includes a first metal layer, a material of the first metal layer includes Cu, a content of the Cu is greater than or equal to 99%, and a thickness of the first metal layer is greater than 2 μm; and
an electronic element, disposed on a side of the first conductive layer facing away from the base substrate, where the electronic element includes an electronic element body and a plurality of pins at a side of the electronic element body facing the base substrate, and the plurality of pins are connected with the plurality of pads.

In some embodiments, in the array substrate provided in the embodiment of the present disclosure, each of the plurality of pads further includes a second metal layer; and the second metal layer is disposed on a side of the first metal layer close to the base substrate; where a material of the second metal layer includes molybdenum-niobium alloy or molybdenum-nickel-titanium alloy.

In some embodiments, the array substrate provided in the embodiment of the present disclosure further includes a plurality of first protective layers between the plurality of pins and the plurality of pads, where a material of the first protective layers is a conductive material.

In some embodiments, in the array substrate provided in the embodiment of the present disclosure, a thickness of each of the first protective layer ranges from 100 Å to 5000 Å.

In some embodiments, in the array substrate provided in the embodiment of the present disclosure, a material of each of the first protective layers includes CuNi.

In some embodiments, in the array substrate provided in the embodiment of the present disclosure, the plurality of pins are connected with the plurality of first protective layers by means of soldering flux, and a material of the soldering flux includes Sn;
each of the plurality of pads further includes: a first intermetallic compound layer disposed on a side of the first metal layer facing away from the second metal layer; and
a material of the first intermetallic compound layer includes CuxSny, where x=1 or x=6, and y=3 or y=5.

In some embodiments, in the array substrate provided in the embodiment of the present disclosure, a thickness of each of the first protective layers is greater than or equal to 1 μm.

In some embodiments, in the array substrate provided in the embodiment of the present disclosure, each of the first protective layers includes a Ni layer and/or a Pd layer; a thickness of the Ni layer ranges from 1 μm to 10 μm, and a thickness of the Pd layer ranges from 10 nm to 500 nm.

In some embodiments, in the array substrate provided in the embodiment of the present disclosure, each of the first protective layers includes a Ni layer and an Au layer; the Au layer disposed on a side of the Ni layer facing away from the base substrate, and a thickness of the Au layer ranges from 10 nm to 500 nm.

In some embodiments, in the array substrate provided in the embodiment of the present disclosure, each of the first protective layers further includes a Pd layer between the Ni layer and the Au layer, and a thickness of the Pd layer ranges from 10 nm to 500 nm.

In some embodiments, in the array substrate provided in the embodiment of the present disclosure, each of the first protective layers includes a plurality of metal material layers stacked with each other; each of the metal material layers are made of different materials; a thickness of each of the metal material layers ranges from 0.1 μm to 10 μm; a material of each of the metal material layers includes at least one of gold, vanadium, chromium, copper, and aluminum.

In some embodiments, in the array substrate provided in the embodiment of the present disclosure, each of the first protective layers includes: a CrCu layer, a Cu layer and an Au layer; and the CrCu layer, the Cu layer and an Au layer are stacked, or
each of the first protective layers includes an Al layer, a Ni layer and a Cu layer; and the Al layer, the Ni layer and the Cu layer are stacked, or
each of the first protective layers includes an Al layer, a NiV layer and a Cu layer; and the Al layer, the NiV layer and the Cu layer are stacked, or
each of the first protective layers includes an Al layer, a V layer and a Cu layer; and the Al layer, the V layer and the Cu layer are stacked.

In some embodiments, in the array substrate provided in the embodiment of the present disclosure, the pins are connected with the first protective layers by means of soldering flux, and a material of the soldering flux includes Sn;
each of the first protective layers includes: a first body layer close to the pad, and a second intermetallic compound layer disposed on a side of the first body layer facing away from the base substrate; and
a material of the second intermetallic compound layer includes MmSnn, where M is a metal in the first protective layer.

In some embodiments, the array substrate provided in the embodiment of the present disclosure further includes second protective layers, where the second protective layers cover at least part of an area of the pins.

In some embodiments, in the array substrate provided in the embodiment of the present disclosure, each of the second protective layers includes: a second body layer close to the pin, and a third intermetallic compound layer dispose on a side of the second body layer facing away from the pin; and a material of the third intermetallic compound layer includes NₐSn_{b}.

In some embodiments, in the array substrate provided in the embodiment of the present disclosure, a material of the second protective layers is same as a material of the first protective layers.

In some embodiments, the array substrate provided in the embodiment of the present disclosure further includes: a first insulating layer between the first conductive layer and the base substrate, and a second conductive layer between the first insulating layer and the base substrate.

In some embodiments, in the array substrate provided in the embodiment of the present disclosure, the first conductive layer includes first wires arranged on a same layer as the pads, the second conductive layer includes second wires, a thickness of each of the first wires is smaller than 2 μm; and a thickness of each of the second wires is smaller than 2 μm.

In some embodiments, in the array substrate provided in the embodiment of the present disclosure, the electronic element is a mini light-emitting diode, LED, a micro LED, or a micro driver chip.

In another aspect, an embodiment of the present disclosure further provides an electronic apparatus, which includes the array substrate provided in any one of the embodiments of the present disclosure.

### BRIEF DESCRIPTION OF THE DRAWINGS

FIG. 1 is a schematic structural diagram of an array substrate provided in the related art.

FIG. 2 shows scanning electron microscope (SEM) photographs after pins of an electronic element are soldered to a pad in the related art.

FIG. 3 shows SEM photographs after an electronic element and a pad are reworked in the related art.

FIG. 4 is a schematic structural diagram of an array substrate according to an embodiment of the present disclosure.

FIG. 5 shows SEM photographs of a structure corresponding to FIG. 4 after reflow soldering.

FIG. 6 is a schematic structural diagram of another array substrate according to an embodiment of the present disclosure.

FIG. 7 is a schematic structural diagram of yet another array substrate according to an embodiment of the present disclosure.

FIG. 8 shows SEM photographs of a structure shown in FIG. 7 after reflow soldering.

FIG. 9 is a schematic diagram of a comparative test of soldering push-pull forces of electronic elements (a light-emitting diode (LED) and an integrated circuit (IC)) in different areas.

FIG. 10 is a schematic diagram of a comparative test of soldering push-pull forces of electronic elements (LED and IC) with and without an intermetallic compound (IMC) inhibition laver.

FIG. 11 is a schematic structural diagram of still another array substrate according to an embodiment of the present disclosure.

FIG. 12 shows SEM photographs when a material of a pin includes Cu, a surface of the pin is not provided with a second protective layer, and a surface of a pad is provided with a first protective layer.

FIGS. 13 to 16 are schematic structural diagrams of some other array substrates according to an embodiment of the present disclosure.

FIGS. 17A to 17G each show a schematic diagram of a section when each step of manufacturing the structure shown in FIG. 7 according to an embodiment of the present disclosure is executed.

FIGS. 18A to 18I each show a schematic diagram of a section when each step of manufacturing the structure shown in FIG. 15 according to an embodiment of the present disclosure is executed.

FIG. 19 is a schematic structural diagram of a top view of an array substrate according to an embodiment of the present disclosure.

### DETAILED DESCRIPTION OF THE EMBODIMENTS

For making objectives, technical solutions and advantages of embodiments of the present disclosure clearer, the technical solutions of embodiments of the present disclosure will be clearly and completely described below in conjunction with the accompanying drawings in embodiments of the present disclosure. Apparently, embodiments described are some embodiments rather than all embodiments of the present disclosure. Embodiments in the present disclosure and features of embodiments can be combined with each other without conflict. Based on embodiments of the present disclosure, all other embodiments obtained by those of ordinary skill in the art without making creative efforts fall within the scope of protection of the present disclosure.

Unless otherwise defined, technical or scientific terms used in the present disclosure should have ordinary meanings as understood by those of ordinary skill in the art to which the present disclosure belongs. “Include”, “comprise”, and other similar words used in the present disclosure indicate that elements or objects before the word include elements or objects after the word and their equivalents, without excluding other elements or objects. “Connection”, “connected”, and other similar words are not limited to physical or mechanical connections, but can include electrical connections, which can be direct or indirect. “Inside”, “outside”, “upper”, “lower”, etc. are only used to indicate a relative positional relation. After an absolute position of the described object changes, the relative positional relation may also change accordingly.

It should be noted that a size and a shape of each figure in the drawings do not reflect a true scale, but only for illustrating the present disclosure. Throughout the drawings, identical or similar reference numerals denote identical or similar elements or elements having identical or similar functions.

In the related art, in order to complete fixed connection between an electronic element and pads, it is necessary to provide soldering flux on pads to be electrically connected with the electronic element on a base substrate, or provide soldering flux on pins of the electronic element, and then the electronic element is arranged in contact with the pads in an aligned manner. For example, at a high temperature from 230° C. to 260° C. the soldering flux is melted and well wetted, and then cooled quickly, so as to achieve the fixed connection between the electronic element and the pads.

The pads are generally made of copper, but the copper is likely to be oxidized, such that it is necessary to conduct surface treatment on the pads. An effect of surface treatment of the pads is mainly to prevent copper oxidation and ineffective electrical connection. Then the pads after surface anti-oxidation treatment are soldered to the pins of the electronic element by means of the soldering flux. However, the inventor of the present disclosure finds that an intermetallic compound (IMC) may be formed between the soldering flux and topmost materials of the pads or the pins of the electronic element during reflow soldering, and a thickness and composition of the intermetallic compound have a functional relation with time, a temperature and an application condition of a soldering process. Meanwhile, internal stress at soldering positions (soldering points) between the pads and the pins of the electronic element may be changed. For example, with increase in the thickness of the intermetallic compound, the internal stress tends to gradually increase, such that brittle cracking or even fracture at the soldering points may be caused, and further connection strength and reliability between the pads and the pins may be influenced. In addition, if the thickness of the intermetallic compound is too great, the pads may be excessively eroded. such that soldering strength and soldering stability may be decreased, and finally ineffective soldering of the electronic element and the pads may be caused.

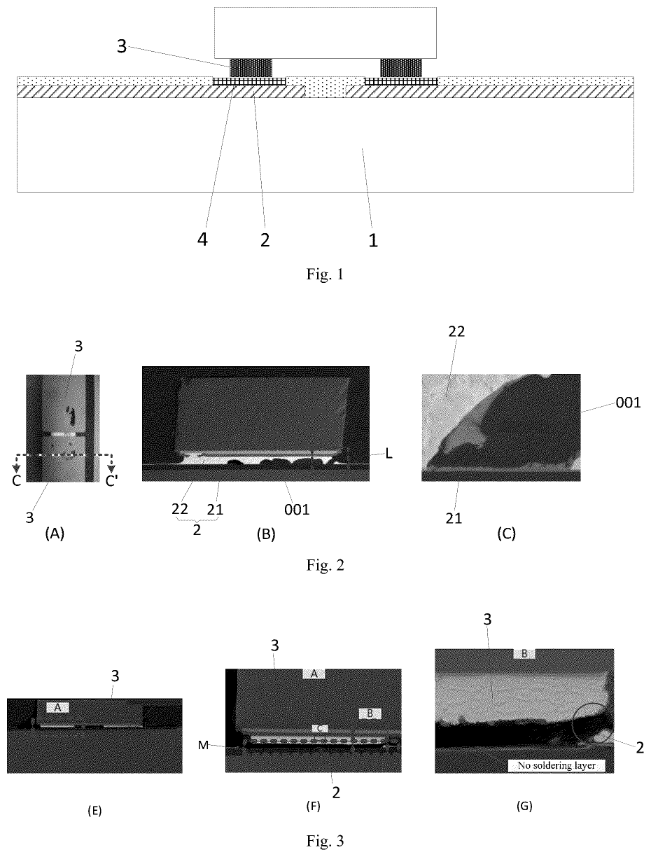

In some embodiments, as shown in FIGS. 1 and 2. FIG. 1 is a schematic diagram of a section before reflow soldering of pads 2 on a base substrate 1 and pins 3 of an electronic element in the related art. (A) in FIG. 2 is a scanning electron microscope (SEM) photograph of a soldering position of a pin 3 of the electronic element and a pad 2 after reflow soldering in the related art, (B) in FIG. 2 is a schematic diagram of a section in direction CC′ in (A) in FIG. 2, and (C) in FIG. 2 is an enlarged schematic diagram of dotted box L in (B) in FIG. 2. Anti-oxidation layers 4 are arranged on surfaces of the pads 2, and each pad 2 includes a buffer layer 21 (for example, MoNb) at the bottom and a main material layer 22 on the buffer layer 21, and the main material layer 22 generally has a thickness smaller than 1 μm. It may be seen from (B) and (C) in FIG. 2 that after reflow soldering, in a partial area of the pad 2, the main material layer 22 is almost completely eroded while the buffer layer 21 is also partially eroded, such that only a part of the buffer layer 21 is left, and further a soldering cavity 001 is formed, Therefore, after reflow soldering, a first problem caused by erosion of the pad 2 is that at a position of the soldering cavity 001 caused by the erosion of the pad 2, water and oxygen corrosion is likely to occur, such that other positions of the pad 2 may be corroded.

In addition, the inventor of the present disclosure finds that in a soldering process, erosion degrees of the pads may be inconsistent along with fluctuation of processes (such as soldering time and a temperature), and erosion may be divided into three conditions according to different erosion degrees: (1) erosion is slight. where IMCs are only formed in areas where the pads are located, around which there is no trace of soldering diffusion; (2) erosion is aggravated, where IMCs extend to areas around the pads and form heat affected areas; and (3) erosion is further aggravated. where local IMC accumulation growth occurs in soldering heat affected areas, and further folded areas are formed. The above three conditions may influence soldering strength. Therefore, erosion of the pads may further cause a problem of unstable soldering strength.

In some embodiments, unfixed soldering or soldering position deviation may occur between the pads and the pins of the electronic element, such that the electronic element and the pins are required to be removed from the corresponding pads to be reworked. As shown in FIG. 3, (E) in FIG. 3 is an SEM photograph after an electronic element and a pad are reworked in the related art, (F) in FIG. 3 is an enlarged schematic diagram of position A in (E) in FIG. 3, and (G) in FIG. 3 is an enlarged schematic diagram of position B in (F) in FIG. 3. It may be seen from dotted box M in (F) in FIG. 3 that a pad 2 is completely eroded during reflow soldering. It may be seen from (G) in FIG. 3 that there is no residue (no soldering layer) at a position where the pad 2 is completely eroded, and if soldering is conducted again, only a part (in a dotted circle), not eroded near a corresponding original soldering position, of the pad 2 may be used to be connected with the electronic element, which causes a great risk of open circuit. Therefore, erosion of the pads 2 may further cause a problem that reworking cannot be conducted.

To sum up, in a soldering process of the electronic element and the pads in the related art, problems such as pad corrosion, unfixed soldering and inability to rework pads due to erosion of the pads may be caused.

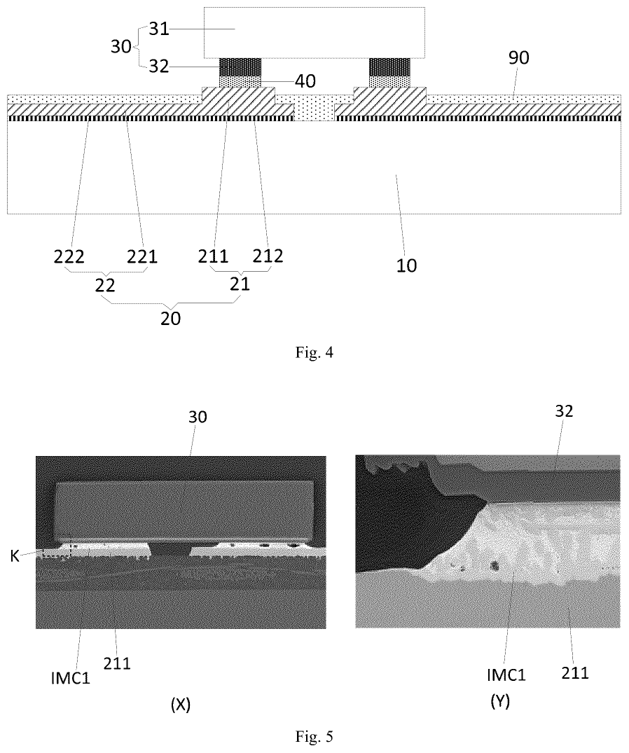

In order to solve problems in a soldering process in the related art, an embodiment of the present disclosure provides an array substrate. The array substrate may be configured to display or provide backlight. As shown in FIG. 4, the array substrate includes:
a base substrate 10;
a first conductive layer 20 disposed on the base substrate 10, where the first conductive layer 20 includes a plurality of pads 21, each pad 21 includes a first metal layer 211, a material of the first metal layer 211 includes Cu, a content of the Cu is greater than or equal to 99%, and a thickness of the first metal layer 211 is greater than 2 μm; and
an electronic element 30 disposed on a side of the first conductive layer 20 facing away from the base substrate 10, where the electronic element 30 includes an electronic element body 31 and a plurality of pins 32 at one side of the electronic element body 31 facing the base substrate 10, and the pins 32 are connected with the pads 21.

In some embodiments, FIG. 4 is a schematic diagram of the pins 32 and the pads 21 before reflow soldering. The pins 32 are bonded to the pads 21 by means of adhesive soldering flux 40, and materials of the soldering flux 40 generally include Sn, Ag, Cu, etc., where a content of Sn ranges from 90% to 99%. When the pins 32 are soldered to the pads 21 through reflow soldering, components in the pins 32 and/or the pads 21 may form intermetallic compounds (IMC1) with Sn in the soldering flux 40. As shown in FIG. 5, (X) in FIG. 5 is an SEM photograph of a structure corresponding to FIG. 4 after reflow soldering, and (Y) in FIG. 5 is an enlarged schematic diagram of dotted box K in (X) in FIG. 5. A thickness of each first metal layer 211 is greater than 10 μm, and a part, eroded by Sn in the soldering flux 40, of the first metal layer 211 has a thickness about 1.5 μm, such that a size of the first metal layer 211 remains 80% or above after reflow soldering. Therefore, in order to ensure that Sn in the soldering flux 40 does not erode and penetrate the pad 21, a thickness of the first metal layer 211 of the pad 21 before reflow soldering is required to be at least greater than 1.5 times of that of the part, eroded by the soldering flux 40, of the first metal layer during reflow soldering. For example, the first metal layer 211 may have a thickness greater than 2 μm. Therefore, according to the array substrate provided in the embodiment of the present disclosure, a thickness of the first metal layers 211 in the pads 21 is set to be greater than 2 μm, such that when the pins 32 of the electronic element 30 are soldered to the pads 21 through reflow soldering, Sn in the soldering flux 40) cannot erode and penetrate the first metal layers 211, and further soldering strength between the pads 21 and the pins 32 is ensured.

In some embodiments, a thickness of the soldering flux 40 generally ranges from 5 μm to 50 μm.

In some embodiments, the electronic element includes an inorganic light-emitting diode having a size of 100 microns or below, or a micro driver chip having a size of 100 microns or below. The inorganic light-emitting diode having a size of 100 microns or below may be a mini light-emitting diode (LED) or a micro LED. A size of the mini LED ranges from about 100 μm to 600 μm, and a size of micro LED is smaller than 100 μm. The micro driver chip may be a chip configured to provide a signal for the inorganic light-emitting diode so as to make the inorganic light-emitting diode emit light.

In an embodiment, the array substrate includes a light-emitting area and a binding area, where pads in the light-emitting area are soldered to the inorganic light-emitting diode, pads in the binding area are bound to the driver chip, and the driver chip is configured to drive the inorganic light-emitting diode to emit light.

In some embodiments, as shown in FIG. 4. the first conductive layer 20 further includes first wires 22. A main difference between the first wires 22 and the pads 21 is that surfaces of the first wires 22 facing away from the base substrate are covered with other film layers such as insulating layers, while surfaces of the pads 21 away from the base substrate are exposed. In some embodiments, the first wires 22 include third metal layers 221 arranged on the same layer as the first metal layers 211 and directly electrically connected. The pins 32 are soldered to the exposed pads 21, such that only a thickness of the first metal layer 211 at positions of the pads 21 may be increased, that is, a thickness of the third metal layers 221 in the first wires 22 is smaller than that of the first metal layers 211 at positions of the pads 21. For example, conductive film layers having the same function may be made through a one-off patterning process, and then an electroplating process is conducted only on positions corresponding to the pads 21, such that a thickness of the conductive film layers in the areas may be increased. Optionally, a thickness of the third metal layer 221 at a position of each first wire 22 may be smaller than 2 μm, for example, 0.6 μm, 1 μm, or 2 μm, and a thickness of the first metal layer 211 at a position of each pad 21 may be 2.5 μm, 3 μm, 5 μm, or 10 μm.

It should be noted that in the embodiment of the present disclosure, a thickness of the third metal layers 221 included in the first wires 22 is smaller than a thickness of the first metal layers 211 included in the pads 21, for example. In some embodiments, the thickness of the first metal layers 211 and the thickness of the third metal layers 221 may be increased at the same time, that is, a thickness of the pads 21 is the same as a thickness of the first wires 22.

It should be noted that an electroplating process is a process of plating a surface of a base metal with a film layer containing a specific metal according to a principle of chemical electrolysis under the action of an external electric field. In some embodiments, the electroplating process is a technology of reducing metal ions on a surface of the base metal as a cathode through migration of positive and negative ions in an electrolyte solution containing metal ions, and preparing a metal coating on the base metal. For example, when the electrolyte solution contains Cu²⁺, the base metal may be plated with a copper film layer. An acidic copper sulfate plating solution has advantages of desirable dispersion ability and deep plating ability, high current efficiency and low cost, so as to be widely used in printed board manufacturing. The electrolyte solution is generally composed of copper sulfate (CuSO₄), sulfuric acid (H₂SO₄), hydrochloric acid (chloride ions Cl⁻ play a main role), and organic additives. The copper sulfate is main salt and a main source of Cu²⁺ in the solution, such that a concentration of the copper sulfate should be controlled during preparation. Plating solutions commonly used include a sulfate plating solution, a direct pyrophosphate plating solution and a cyanide plating solution, and an acid sulfate plating solution is commonly used at present.

In the array substrate provided in the embodiment of the present disclosure, as shown in FIG. 4, each pad 21 further includes a second metal layer 212, the second metal layer 212 is disposed on a side of the first metal layer 211 close to the base substrate 10; each first wire 22 further includes a fourth metal layer 222, and the fourth metal layer 222 is disposed on a side of the third metal layer 221 close to the base substrate 10; and the first metal layer 211 is arranged on the same layer as the third metal layer 221, and the fourth metal layer 222 is arranged on the same layer as the second metal layer 212. Materials of the second metal layers 212 and the fourth metal layers 222 include molybdenum-niobium alloy or molybdenum-nickel-titanium alloy, and the second metal layers 212 and the fourth metal layers 222 may be configured to improve adhesion to a film layer close to the base substrate. The first metal layers 211 and the third metal layers 221 are configured to transmit electrical signals, and more than 99% of components of materials of the first metal layers 211 and the third metal layers 221 are Cu.

It may be understood that the first conductive layer 20 includes the pads 21 and the first wires 22, the first conductive layer 20 is composed of two stacked film layers, that is, each pad 21 includes the second metal layer 212 and the first metal layer 211 that are stacked, and each first wire 22 includes the fourth metal layer 222 and the third metal layer 221 that are stacked.

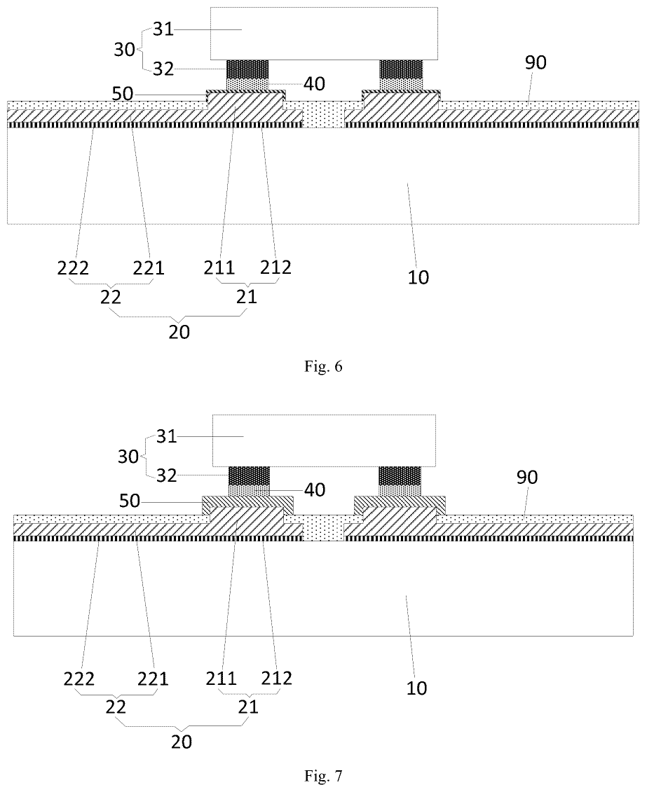

As shown in FIGS. 6 and 7, the array substrate provided in the embodiment of the present disclosure further includes first protective layers 50 between the pins 32 and the pads 21, where the first protective layers 50 are made of conductive materials.

It should be noted that both FIGS. 6 and 7 are schematic diagrams of the pins 32 and the pads 21 before reflow soldering.

In some embodiments, the first metal layers of the pads are mainly made of copper, but the copper is likely to be oxidized, such that it is necessary to conduct surface treatment on the pads. An effect of surface treatment of the pads is mainly to prevent copper oxidation and ineffective electrical connection. As shown in FIG. 6, the first protective layers 50 may be made of materials having anti-oxidation functions, so as to protect the first metal layers 211 of the pads 21 against external water vapor oxidation. A thickness of each first protective layer 50 ranges from 100 Å to 5000 Å, and a material of each first protective layer 50 may include, but is not limited to, Cu alloys such as CuNi, CuMgAl, or CuNiAl. Therefore, the structure shown in FIG. 6 may ensure that positions of the pads 21 are not eroded and penetrated, such that soldering stability is improved, and the pads 21 cannot be oxidized by external water vapor.

In the array substrate provided in the embodiment of the present disclosure, as shown in FIG. 6, the pins 32 are connected with the first protective layers 50 by means of soldering flux 40, and a material of the soldering flux includes Sn.

As shown in FIG. 5, FIG. 5 shows SEM photographs of a structure shown in FIG. 6 after reflow soldering. Each pad 21 further includes: a first intermetallic compound layer IMC1 at a side of the first metal layer 211 facing away from the second metal layer 212; and a material of the first intermetallic compound layer IMC1 includes CuₓSn_{y}, where x=1 or x=6, and y=3 or y=5. Thicknesses and thickness ratios of the CuₓSn_{y} series intermetallic compounds vary with a temperature, time, an environment and a use condition of reflow soldering, where a CuSn₃ intermetallic compound is disposed on a side of each pad 21 closest to the base substrate 10, and a Cu₆Sn₅ intermetallic compound is disposed on a side of each pad 21 facing away from the base substrate 10.

It should be noted that the first protective layers 50 having an anti-oxidation function in FIG. 6 are generally made of Cu alloy, Sn in the soldering flux 40 may react with a metal of the first protective layers 50 so as to form intermetallic compounds during reflow soldering, but the first protective layers 50 having the anti-oxidation function are relatively thin (usually several hundred angstroms), such that after the first protective layers 50 are eroded by Sn, Sn in the soldering flux 40 may further react with materials in the first metal layers 211 of the pads 21, so as to generate intermetallic compound layers. In the embodiment of the present disclosure, the first metal layers 211 are mainly made of Cu, and intermetallic compound layers generated through reactions of Sn with Cu in the first protective layers 50 and Cu in the first metal layers 211 are called the first intermetallic compound layers IMC1. The material of each first intermetallic compound layer IMC1 includes CuₓSn_{y}, where x=1 or x=6, and y=3 or y=5. Certainly, Sn in the soldering flux 40 may further react with other metals in the first protective layers 50 so as to generate intermetallic compounds, but contents of other metals in the first protective layers 50 are very low: which may be ignored.

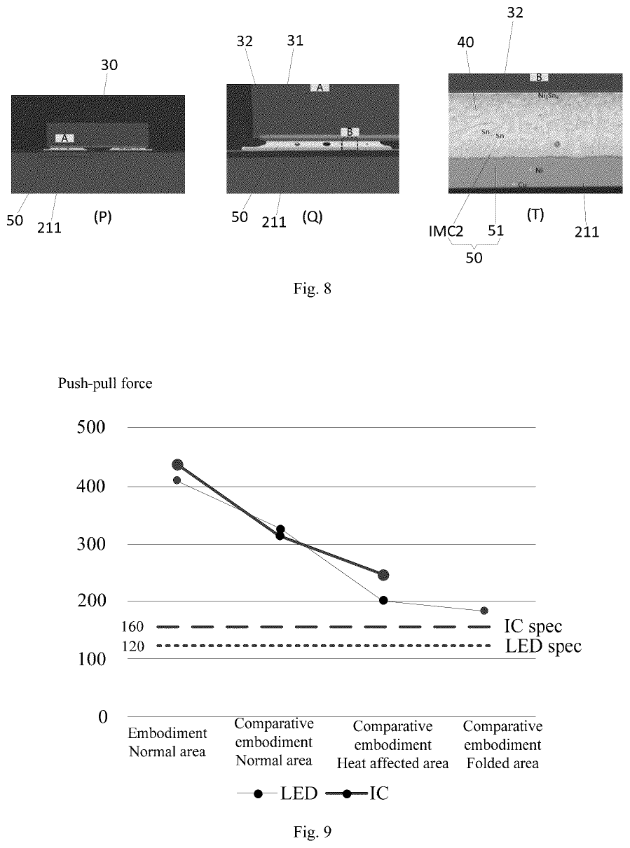

In the array substrate provided in the embodiment of the present disclosure, as shown in FIG. 7, a thickness of each first protective layer 50 is greater than or equal to 1 μm. In some embodiments, even if a thickness of each first metal layer 211 is increased in the structure shown in FIG. 4, it is still possible that the first metal layer 211 is completely eroded by Sn in the soldering flux 40 if the soldering flux 40 used in reflow soldering is too thick. Therefore, in order to further prevent the first metal layer 211 from being eroded, the first protective layer 50 may be made of a material capable of preventing Sn in the soldering flux 40 from diffusing to the first metal layer 211, that is, the first protective layer 50 may prevent Sn in the soldering flux 40 from reacting with Cu in the first metal layer 211 so as to form an IMC, after the reflow soldering is finished, the pad 21 is not eroded by Sn and remains intact, and the first protective layer 50 may effectively prevent Sn from infiltrating into the first metal layer 211. As shown in FIG. 8, (P) in FIG. 8 is an SEM photograph of the structure shown in FIG. 7 after reflow soldering, (Q) in FIG. 8 is an enlarged schematic diagram of dotted box A in (P) in FIG. 8, and (T) in FIG. 8 is an enlarged schematic diagram of dotted box B in (Q) in FIG. 8. It may be seen that erosion of the pad 21 (the first metal layer 211) does not occur.

In the array substrate provided in the embodiment of the present disclosure, as shown in FIG. 7, each first protective layer 50 may include a Ni layer and/or a palladium (Pd) layer. In some embodiments, the first protective layer 50 may only include a Ni layer, or, the first protective layer 50 may only include a Pd layer, or, the first protective layer 50 may include a Ni layer and a Pd layer that are stacked. A thickness of the Ni layer ranges from 1 μm to 10 μm, and a thickness of the Pd layer ranges from 10 nm to 500 nm. The first protective layer 50 within the thickness range may well prevent Sn in the soldering flux 40 from diffusing to the first metal layer 211.

In some embodiments, the Ni layer and the Pd layer may be made through electroplating or chemical plating.

In the array substrate provided in the embodiment of the present disclosure, each first protective layer 50 shown in FIG. 7 may only include a Ni layer, for example, In some embodiments, each first protective layer 50 may further include an Au layer at one side of the Ni layer facing away from the base substrate 10, and a thickness of the Au layer ranges from 10 nm to 500 nm. In some embodiments, the Ni layer may be made through chemical plating, and then a surface of the Ni layer is plated with gold, such that the Ni layer and the gold form the first protective layer 50 together, that is, the first protective layer 50 may be a stacked structure composed of the Ni layer and the Au layer.

In the array substrate provided in the embodiment of the present disclosure, each first protective layer 50 may be a stacked structure including a Ni layer, an Au layer and a Pd layer, where the Pd layer is located between the Ni layer and the Au layer, and a thickness of the Pd layer ranges from 10 nm to 500 nm. Pd has strong thermal diffusion ability and may improve soldering reliability. In some embodiments, the Ni layer, the Pd layer and the Au layer may be made in sequence through chemical plating.

In the array substrate provided in the embodiment of the present disclosure, each first protective layer 50 shown in FIG. 7 only includes a Ni layer, for example. In some embodiments, the first protective layer 50 may also include a plurality of stacked metal material layers, all the metal material layers may be made of different materials, a thickness of each metal material layer ranges from 0.5 μm to 10 μm, and a material of each metal material layer may include at least one of gold, vanadium, chromium, copper, and aluminum. In some embodiments, for example, each first protective layer includes a CrCu layer, a Cu layer and an Au layer that are stacked, or, each first protective layer includes an Al layer, a Ni layer and a Cu layer that are stacked, or, each first protective layer includes an Al layer, a NiV layer and a Cu layer that are stacked, or, each first protective layer includes an Al layer, a V layer and a Cu layer that are stacked. Certainly, the present disclosure is not limited to the above.

In the array substrate provided in the embodiment of the present disclosure, as shown in FIG. 7, the pins 32 are connected with the first protective layers 50 by means of soldering flux 40, and a material of the soldering flux 40 includes Sn.

As shown in FIG. 8, each first protective layer 50 includes: a first body layer 51 close to the first metal layer 211, and a second intermetallic compound layer IMC2 disposed on a side of the first body layer 51 facing away from the base substrate 10; and a material of the second intermetallic compound layer IMC2 includes MₘSnₙ, where M is a metal having a maximum proportion in the first protective layer 50.

In some embodiments, as shown in FIG. 8, each first protective layer 50 is mainly made of Ni in FIG. 8, for example. Sn in the soldering flux may react with Ni in the first protective layer 50 so as to generate an intermetallic compound. For example, a material of the second intermetallic compound layer IMC2 generated includes Ni₃Sn₄ (that is, M is Ni, m=3, n=4). Certainly, when a material of each first protective layer further includes Au, Pd, etc., Sn may also react with Au, Pd, etc. so as to generate intermetallic compounds.

It should be noted that in FIG. 8, part of Sn in the soldering flux 40 reacts with Ni in each first protective layer 50 so as to generate an intermetallic compound. In some embodiments, Sn in the soldering flux 40 may also completely react with Ni in the first protective layer 50 so as to generate an intermetallic compound. An actual reaction situation is related to a thickness of the first protective layer 50, reaction time, etc.

In order to explore a relation between soldering strengths in presence and absence of the first protective layers 50 (which are configured to prevent Sn in the soldering flux from diffusing to the first metal layers 211), testing is conducted under conditions that surfaces of the pads 21 are provided with no first protective layers 50 and with the first protective layers 50, for example. When no first protective layer 50 is arranged on a surface of each pad 21 and a thickness of the pad 21 is not increased (with reference to the structure shown in FIG. 1), erosion degrees of the pads may be inconsistent along with fluctuation of a reflow soldering process. However, as shown in FIG. 7, the first protective layers 50 whose material includes Au and/or Ni are additionally provided in the embodiment of the present disclosure, such that Sn in the soldering flux may be prevented from diffusing into the pads 21 to erode the pads 21, which makes a soldering layer more stable. As shown in FIG. 9, FIG. 9 is a schematic diagram of a comparative test of soldering push-pull forces of electronic elements (an LED and an integrated circuit (IC)) in different areas. It may be seen that in the embodiment in which the first protective layers 50 are added and the first protective layers 50 contain NiAu, the electronic element after reflow soldering is capable of bearing a larger push-pull force (corresponding to a normal area of the embodiment), and it is indicated that a soldering effect is better; and in a comparative embodiment in which no first protective layer 50 is arranged, push-pull forces in areas where the pads are located (corresponding to normal areas of the comparative embodiment), a heat affected area (corresponding to a heat affected area of the comparative embodiment) and a folded area (corresponding to a folded area of the comparative embodiment) gradually decrease, such that soldering strength may decrease from 40% to 60%. Therefore, after the first protective layers 50 are added in the embodiment of the present disclosure, soldering strength of the areas where the pads are located is more stable, and increases by about 25% or above, which is increased by 200% or above compared with the folded area of the comparative embodiment.

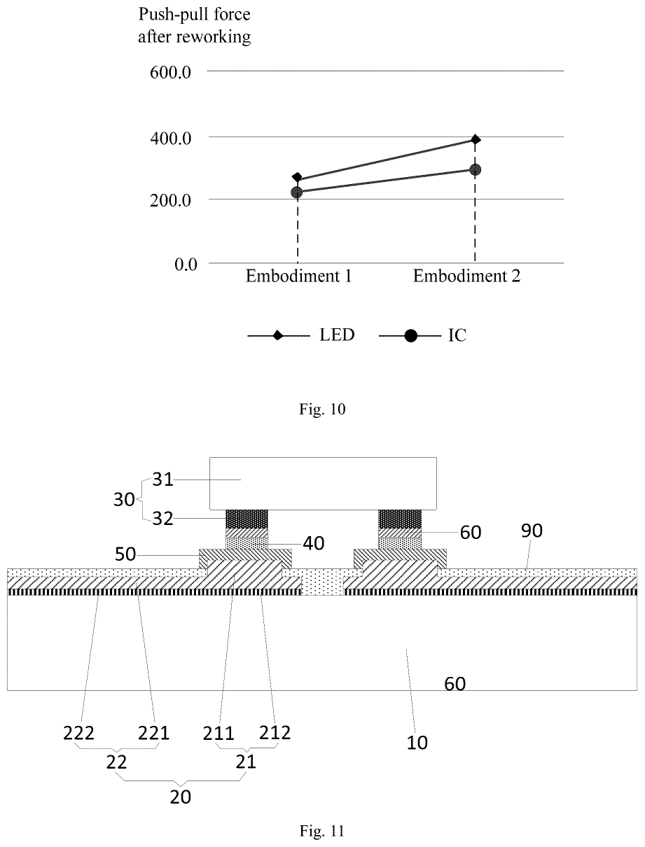

The inventor tested solderability of pads. As shown in FIGS. 8 and 10, in FIG. 8, the first protective layer 50 may be arranged to prevent Sn in the soldering flux 40 from diffusing to the first metal layer 211 and corroding the pad 21, and further integrity of the pad 21 is ensured. FIG. 10 shows a schematic diagram of a comparative test of soldering push-pull forces under conditions that the electronic elements (LED, IC) are provided with no first protective layer 50 capable of preventing Sn from diffusing to the first metal layer 211 (corresponding to Embodiment 1, where the first metal layer 211 of the pad is not thickened, a surface of the first metal layer 211 is only provided with the first protective layer 50 having an anti-oxidation function, and the first protective layer 50 is made of CuNi), and the electronic components are provided with the first protective layer 50 capable of preventing Sn from diffusing to the first metal layer 211 (corresponding to Embodiment 2, where a material of each first protective layer 50 includes NiAu, for example). It may be seen that when the material of the first protective layer 50 is capable of preventing Sn in the soldering flux from diffusing to the first metal layer 211 to form an IMC in reflow soldering, a soldering push-pull force after reworking is larger, for example, the push-pull force may be increased by 50%, and it is indicated that a soldering condition is OK and soldering strength is more stable.

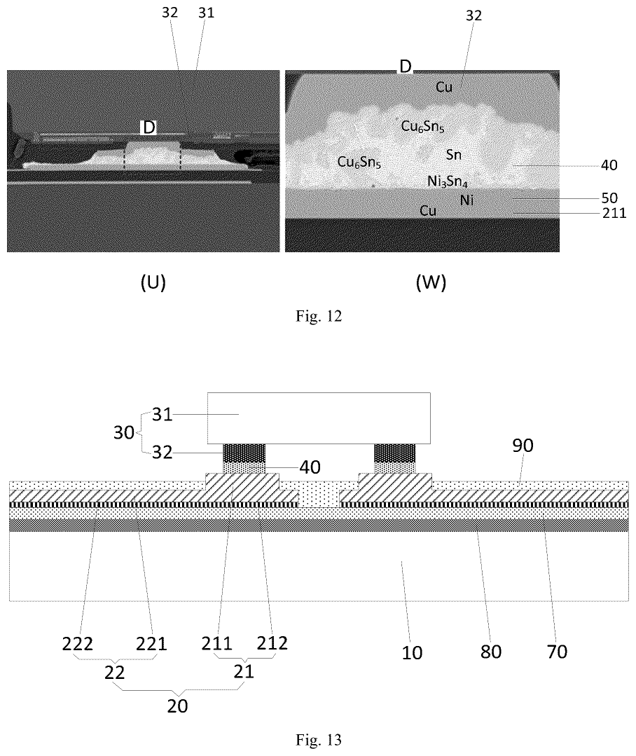

In some embodiments, when materials of the pins of the electronic element are metals (for example, Cu) that are likely to be eroded, a problem of pin erosion may be solved by adding film layers capable of preventing metal materials of the pins from diffusing into the soldering flux. If no film layer capable of preventing the metal materials of the pins from diffusing into the soldering flux is added, the metal materials of the pins of the electronic element may easily diffuse into the soldering flux so as to generate IMCs. The IMCs generally have a melting point greater than 400° C., and a heating temperature during reworking of the electronic element is smaller than 400° C., such that the IMCs cannot be melt during reworking of the electronic element, excessive growth of the IMCs in the soldering flux may be caused, and a problem of pad damage during reworking of the electronic element may be likely to occur. Therefore, as shown in FIG. 11, the array substrate provided in the embodiment of the present disclosure further includes second protective layers 60, where the second protective layers 60 cover at least partial areas of the pins 32. In some embodiments, a material of the second protective layers 60 may be the same as that of the first protective layers 50, and may be Ni, NiAu, etc., for example. The second protective layers 60 may prevent the metal materials of the pins 32 from diffusing into the soldering flux 40, and further prevent Cu in the pins 32 from diffusing into the soldering flux 40 to form IMCs. As shown in FIG. 12, (U) in FIG. 12 is an SEM photograph when a material of the pin 32 includes Cu, a surface of the pin 32 is provided with no second protective layer 60, and a surface of the pad 21 is provided with the first protective layer 50, and (W) in FIG. 12 is an enlarged schematic diagram of dotted box D in (U) in FIG. 12. It may be seen that when no second protective layer 60 is provided, the pin 32 is eroded and diffuses into the soldering flux, such that an IMC (Cu₆Sn₅) in the soldering flux grows excessively to be greater than 5 μm, and the IMC cannot be melted during reworking, which easily leads to forced disassembly and further leads to pad damage. Therefore, in the embodiment of the present disclosure, preferably, surfaces of the pins 32 are coated with the second protective layer 60 that are used as IMC inhibition layers, such that a problem that the pins are disassembled forcedly, and the pads are damaged during later reworking is avoided.

In some embodiments, FIG. 11 shows a structure of the pins and the pads before reflow soldering. After reflow soldering, each second protective layer 60 may include a second body layer 61 (not shown in the figure) close to the pin 32 and a third intermetallic compound layer IMC3 (not shown in the figure) at one side of the second body layer 61 facing away from the pin 32. A material of the third intermetallic compound layer IMC3 includes NₐSn_{b}, where N is a metal component having a maximum proportion in the second protective layer 60.

In some embodiments, when each second protective layer 60 is mainly made of Ni, Sn in the soldering flux 40 may react with Ni in the second protective layer 60 so as to generate an intermetallic compound. For example, a material of the third intermetallic compound layer IMC3 generated includes Ni₃Sn₄ (that is, N is Ni, m=3, n=4). Certainly, when a material of each second protective layer further includes Au, Pd, etc., Sn may also react with Au, Pd, etc. so as to generate intermetallic compounds.

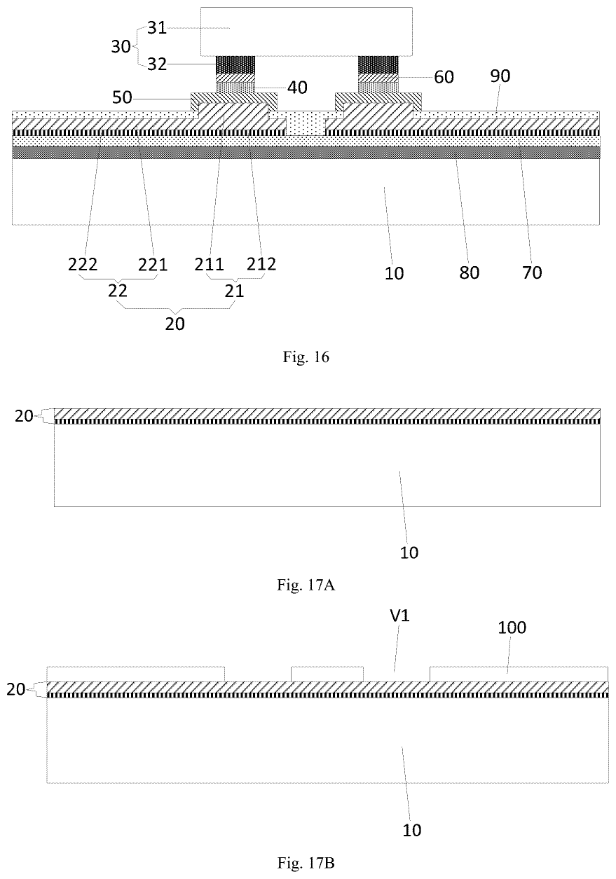

As shown in FIGS. 13 and 16, the array substrate provided in the embodiment of the present disclosure further includes: a first insulating layer 70 between the first conductive layer 20) and the base substrate 10, and a second conductive layer 80 between the first insulating layer 70 and the base substrate 10.

In some embodiments, the second conductive layer 80 includes second wires electrically connected with the pads 21, which may be a common voltage wire (GND), a drive voltage wire (VLED), a source power wire (PWR), a source address wire (DI), etc., for example. Each second wire may have a thickness smaller than 2 μm, for example, 0.6 μm, 1 μm, 2 μm, etc. Optionally, a material of the second conductive layer 80 includes copper. For example, the second conductive layer 80 may be made into a stacked material, for example, MoNb/Cu/MoNb, through sputtering. MoNb at the bottom is configured to improve adhesion between the second conductive layer 80 and a lower film layer, Cu in the middle is configured to ensure a low resistivity of the second conductive layer 80, and MoNb at the top is configured to improve oxidation resistance of the second conductive layer 80. Alternatively, the second conductive layer 80 may be formed through electroplating, for example, a seed layer MoNiTi is formed first to improve a nucleation density of grains, a Cu layer is formed through electroplating, and then a MoNiTi layer for preventing oxidation of the Cu layer is made.

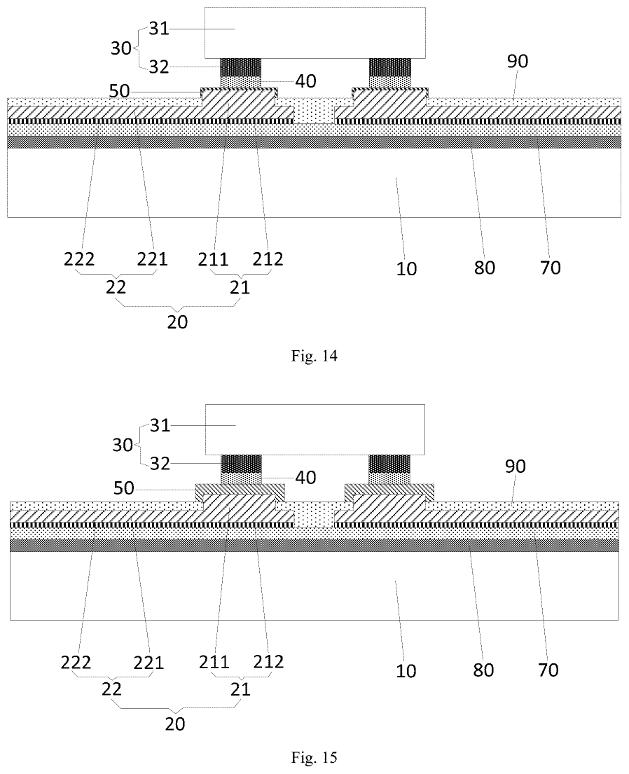

As shown in FIGS. 4, 6, 7, 11 and 13 to 16, the array substrate provided in the embodiment of the present disclosure further includes a second insulating layer 90 at one side of the first conductive layer 20 facing the soldering flux 40, and the second insulating layer 90 exposes the pads 21.

In some embodiments, in theory, it is only necessary to design the first protective layers, capable of preventing Sn in the soldering flux from diffusing to the first metal layers of the pads, on the surfaces of the pads, such that material cost of the first protective layers is reduced. In some embodiments, the first protective layers may also be made on surfaces of the first wires of the first conductive layer, which does not influence a soldering function.

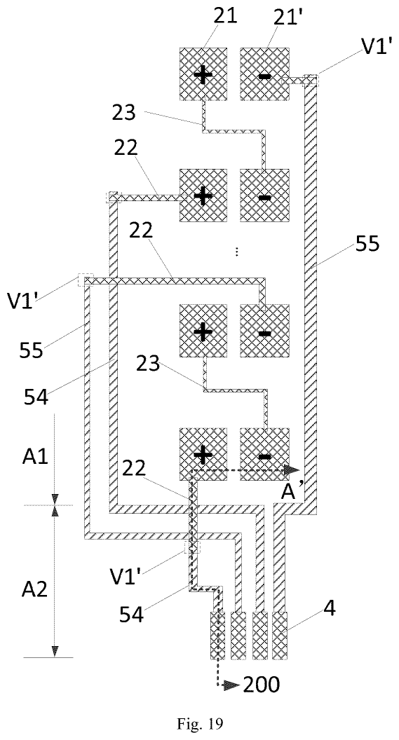

As shown in FIG. 19, FIGS. 4, 6 and 7 are schematic diagrams of several sections in direction AA′ in FIG. 19. The second conductive layer 80 may include anode wires 54 and cathode wires 55 (not shown in FIGS. 4, 6 and 7), and the anode wires 54 and the cathode wires 55 may be each provided with a MoNb layer, a Cu layer and a MoNb layer that are stacked. In order to reduce voltage drop (IR drop), a thickness of the Cu layer is greater than that of the pad 21, and the thickness of the Cu layer is positively related to a product size of a mini LED back panel. A MoNb layer, a Cu layer and a MoNb layer may be made in sequence through sputtering, and the MoNb layer may protect the Cu layer and prevent surface oxidation of the Cu layer.

In some embodiments, in the array substrate provided in the embodiment of the present disclosure, if the electronic element is an inorganic light-emitting diode, the electronic element is bound to pads in a light-emitting area A1. The inorganic light-emitting diode includes anode pins and cathode pins. such that one inorganic light-emitting diode needs to be bound through two pads. The plurality of pads in the embodiment of the present disclosure may be divided into a plurality of pad groups, and specific connection modes of the plurality of pad groups are not limited. In FIG. 19, two adjacent pad groups connected in series are taken as an example for illustration. Each pad group is configured to bind one inorganic light-emitting diode and includes a cathode pad 21′ and an anode pad 21 arranged in pairs. A pad bound to a cathode pin of the inorganic light-emitting diode is called the cathode pad, and a pad bound to an anode pin of the inorganic light-emitting diode is called the anode pad. As shown in FIG. 19, each pad group includes the cathode pad 21′ and the anode pad 21 arranged in pairs, and a film layer structure included in the cathode pad 21′ and a film layer structure included in the anode pad 21 are the same.

Two adjacent groups of pads are connected in series through third wires 23, and the third wires 23 are located on the same layer as the first wires 22. As shown in FIG. 19, in the two pad groups connected in series, an anode pad 21 of one of the pad groups is connected with one first wire 22, and the first wire 22 is electrically connected with an anode wire 54 through a via hole V1′ penetrating an insulating layer; and a cathode pad of the other group is connected with another first wire 22, and the first wire 22 is electrically connected with a cathode wire 55 through another via hole V1 penetrating the insulating layer.

If the electronic element is a micro driver chip, the electronic element is bound to pads of a binding area, and an anode wire 54 is electrically connected with a pad 200 of a binding area A2 through a via hole (not shown in the figure) penetrating the insulating layer; and a cathode pad of another group is connected with another first wire 22, the first wire 22 is electrically connected with a cathode wire 55 through another via hole V1′ penetrating the insulating layer, and the cathode wire 55 is electrically connected with a pad 200 of another binding area A2 through a via hole (not shown in the figure) penetrating the insulating layer.

In FIG. 19, the cathode pads 21′, the anode pads 21, the pads 200 in the binding area A2, wires 11 and wires 12 are arranged on the same layer, and the same filling pattern is used to represent the cathode pads 21′, the anode pads 21. the pads 200 in the binding area A2, the third wires 23 and the first wires 22. The anode wires 54 are arranged on the same layer as the cathode wires 55, and the same filling pattern is used to represent the anode wires 54 and the cathode wires 55.

In some embodiments, the array substrate provided in the embodiment of the present disclosure may further include other functional structures that are familiar to those skilled in the art, which will not be described in detail herein.

Manufacturing methods for a structure including only a first conductive layer 20 as shown in FIG. 7 and a structure including a first conductive layer 20 and a second conductive layer 80 as shown in FIG. 15 will be briefly described below:

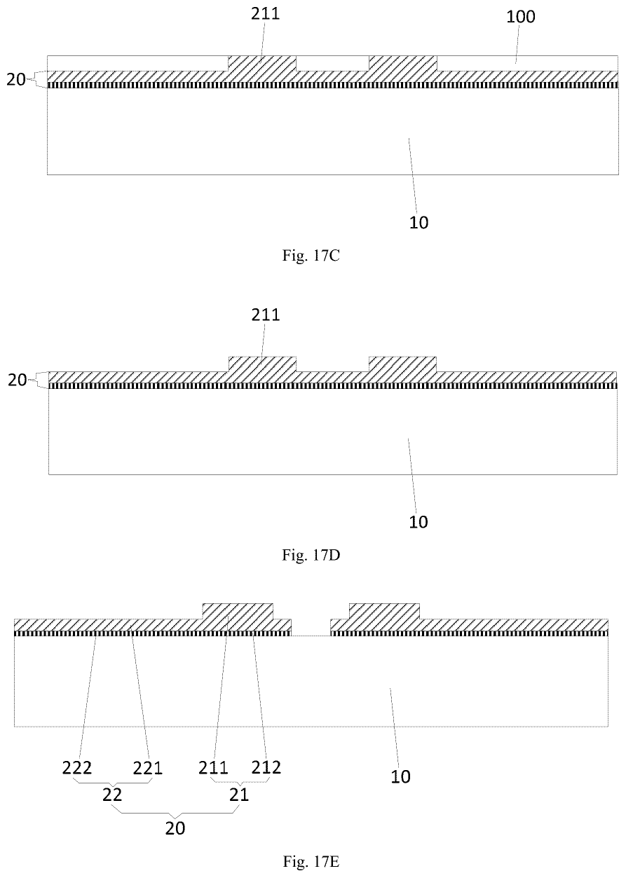

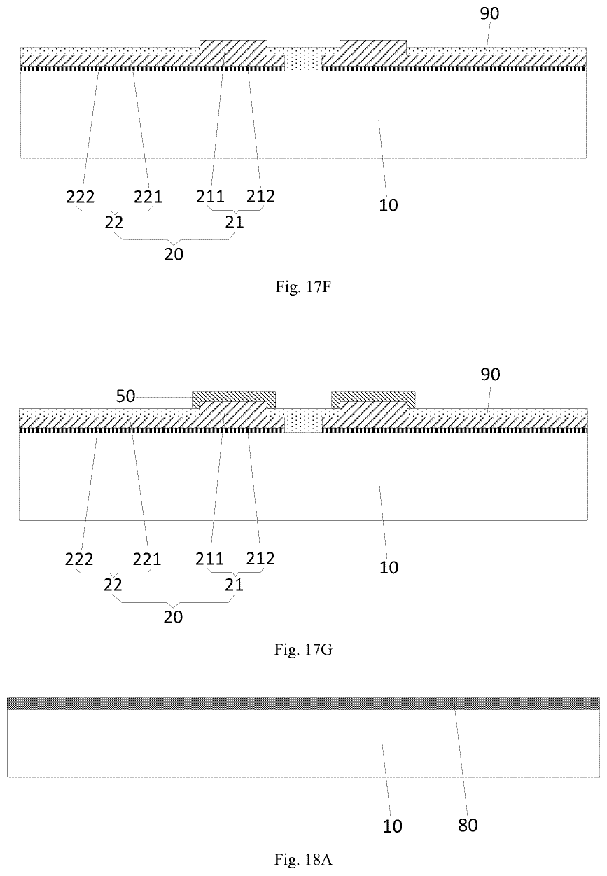

A manufacturing method for the array substrate shown in FIG. 7 includes the following steps that:
(1) a base substrate 10 is provided, and a first conductive layer 20 is disposed on an entire surface of the base substrate 10, as shown in FIG. 17;
(2) an insulation film layer 100 covers a side of the first conductive layer 20 facing away from the base substrate 10, the insulation film layer 100 is patterned, and a hole V1 is formed at a position, corresponding to a position where a pad 21 is to be formed, of the insulation film layer 100, as shown in FIG. 17B;
(3) electroplating is conducted at a position of the hole V1, and further a thickness of a first metal layer 211 is increased, as shown in FIG. 17C;
(4) the insulation film layer 100 is removed, as shown in FIG. 17D;
(5) the first conductive layer 20 is patterned, and a first wire 22 and a pad 21 arranged on the same layer are formed, as shown in FIG. 17E;
(6) a second insulating layer 90 covers a side of the first patterned conductive layer 20 facing away from the base substrate 10, the second insulating layer 90 is patterned, and a hole is formed at a position corresponding to the pad so as to expose the pad 21, as shown in FIG. 17F;
(7) a first protective layer 50 is made on the pad 21, as shown in FIG. 17G; and
(8) a surface of a pin 32 of an electronic element is coated with soldering flux 40, the pin 32 is aligned with the pad 21, and the pin 32 is soldered to the pad 21 through reflow soldering, as shown in FIG. 7.

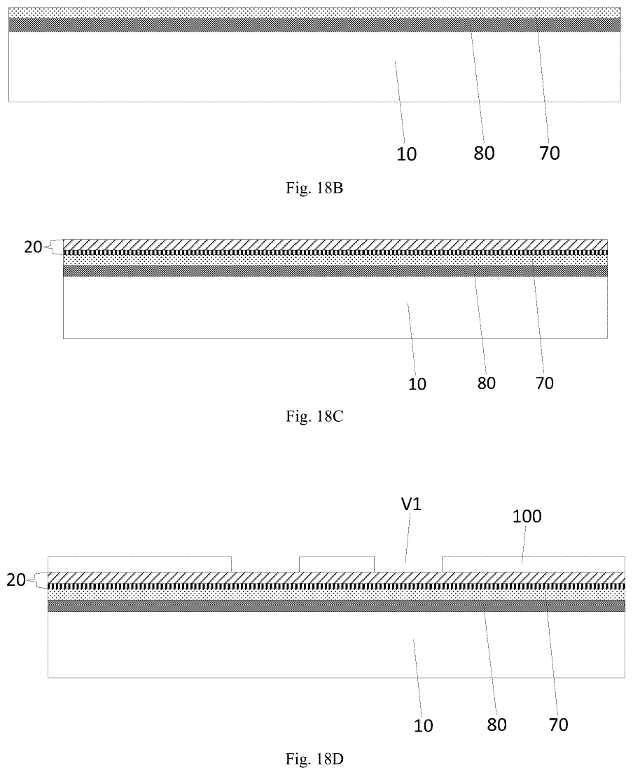

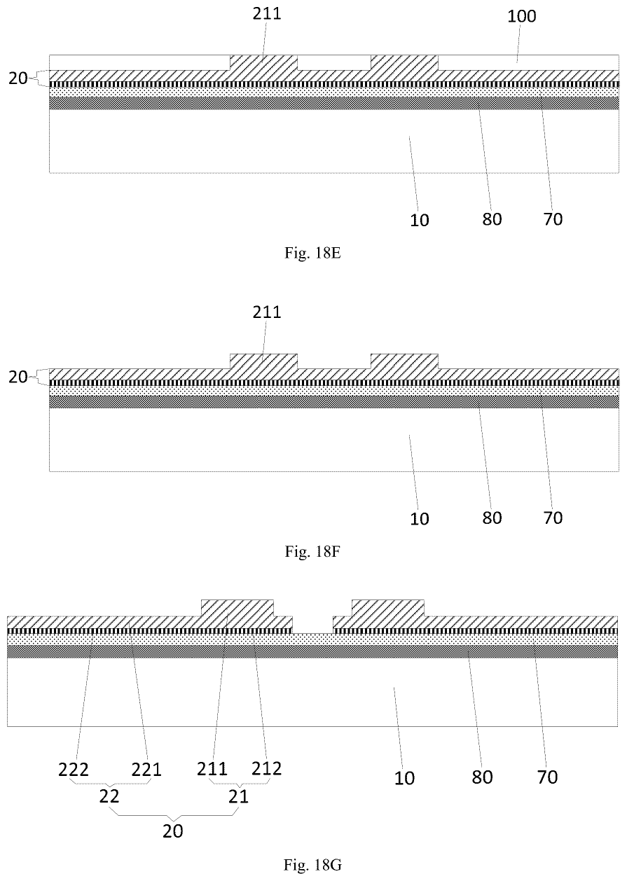

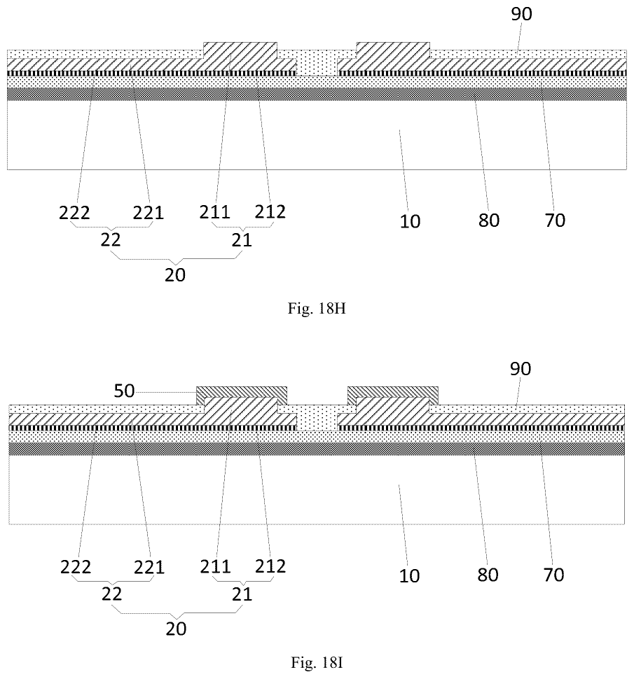

A manufacturing method for the array substrate shown in FIG. 15 includes the following steps that:
(1) a base substrate 10 is provided, a second conductive layer 80 is disposed on an entire surface of the base substrate 10, the second conductive layer 80 is patterned, and the second conductive layer 80 including a second wire (not shown in the figure) is formed, as shown in FIG. 18A;
(2) a first insulating layer 70 covers one side of the second patterned conductive layer 80 facing away from the base substrate 10, the first insulating layer 70 is patterned, and a via hole (not shown in the figure) to be electrically connected with a pad 21 is formed, as shown in FIG. 18B;
(3) a first conductive layer 20 is disposed on an entire surface of one side of first insulating layer 70 facing away from the base substrate 10, as shown in FIG. 18C;
(4) an insulation film layer 100 covers one side of the first conductive layer 20 facing away from the base substrate 10, the insulation film layer 100 is patterned, and a hole V1 is formed at a position, corresponding to a position where the pad 21 is to be formed, of the insulation film layer 100, as shown in FIG. 18D;
(5) electroplating is conducted at a position of the hole V1, and further a thickness of a first metal layer 211 is increased, as shown in FIG. 18E;
(6) the insulation film layer 100 is removed, as shown in FIG. 18F;
(7) the whole first conductive layer 20 is patterned, and a first wire 22 and the pad 21 arranged on the same layer are formed, as shown in FIG. 18G;
(8) a second insulating layer 90 covers one side of the first patterned conductive layer 20 facing away from the base substrate 10, the second insulating layer 90 is patterned, and a hole is formed at a position corresponding to the pad so as to expose the pad 21, as shown in FIG. 18H;
(9) a first protective layer 50 is made on the pad 21, as shown in FIGS. 18I; and
(10) a surface of a pin 32 of an electronic element is coated with soldering flux 40, the pin 32 is aligned with the pad 21, and the pin 32 is soldered to the pad 21 through reflow soldering, as shown in FIG. 15.

In some embodiments, all the above insulating layers may be made of inorganic materials such as silicon nitride or organic materials such as resin. When inorganic materials are used, a thickness of each of the insulating layers ranges from 1200 angstroms to 5000 angstroms, and when organic materials are used, a thickness of each insulating layer ranges from 2 μm to 10 μm.

To sum up, the array substrate provided in the embodiment of the present disclosure may solve the problems of pad corrosion and penetration, unfixed soldering, inability to rework pads, etc. caused by pad erosion when the pins of the electronic element are soldered to the pads in the related art. The embodiment of the present disclosure may improve soldering stability and soldering strength.

Based on the same inventive concept, an embodiment of the present disclosure further provides an electronic apparatus, which includes the array substrate provided in the embodiments of the present disclosure. A problem solving principle of the electronic apparatus is similar to that of the array substrate, so reference may be made to implementation of the array substrate for implementation of the electronic apparatus, which will not be repeated herein. The electronic apparatus may be any product or component having a display or touch function, such as a mobile phone, a tablet computer, a television, a display, a notebook computer, a digital photo frame, and a navigator.

In some embodiments, the electronic apparatus may be a liquid crystal display apparatus, which includes a liquid crystal panel and a backlight source arranged at a non-display side of the liquid crystal panel, where the backlight source includes the array substrate described in any one of the above embodiments. The liquid crystal display apparatus may have more uniform backlight brightness and better display contrast.

In another embodiment, the array substrate in the electronic apparatus may be used as a display substrate. When the array substrate is used as the display substrate, each inorganic light-emitting diode is used as one sub-pixel.

The embodiments of the present disclosure provide the array substrate and the electronic apparatus. The thickness of the first metal layers in the pads made of almost pure Cu materials is set to be greater than 2 μm, such that when the pins of the electronic element are soldered to the pads through reflow soldering, Sn in the soldering flux cannot erode and penetrate the first metal layers, and further soldering strength between the pads and the pins is ensured.

Although preferred embodiments of the present disclosure have been described, those skilled in the art can still make additional changes and modifications to the embodiments once they learn the basic inventive concept. Therefore, the appended claims are intended to be interpreted as including the preferred embodiments and all changes and modifications falling within the scope of the present disclosure.

Apparently, those skilled in the art can make various modifications and variations to the embodiments of the present disclosure without departing from the spirit and scope of the embodiments of the present disclosure. In this way, if these modifications and variations of the embodiments of the present disclosure fall within the scope of the claims of the present disclosure and their equivalent technologies, the present disclosure is also intended to include these modifications and variations.

1. An array substrate, comprising:
a base substrate;
a first conductive layer, disposed on the base substrate, wherein the first conductive layer comprises a plurality of pads, each of the plurality of pads comprises a first metal layer, a material of the first metal layer comprises Cu, a content of the Cu is greater than or equal to 99%, and a thickness of the first metal layer is greater than 2 μm; and
an electronic element, disposed on a side of the first conductive layer facing away from the base substrate, wherein the electronic element comprises an electronic element body and a plurality of pins at a side of the electronic element body facing the base substrate, and the plurality of pins are connected with the plurality of pads.

2. The array substrate according to claim 1, wherein each of the plurality of pads further comprises a second metal layer; and
the second metal layer is disposed on a side of the first metal layer close to the base substrate;
wherein a material of the second metal layer comprises molybdenum-niobium alloy or molybdenum-nickel-titanium alloy.

3. The array substrate according to claim 2, further comprising: a plurality of first protective layers between the plurality of pins and the plurality of pads, wherein a material of the first protective layers is a conductive material.

4. The array substrate according to claim 3, wherein a thickness of each of the first protective layer ranges from 100 Å to 5000 Å.

5. The array substrate according to claim 4, wherein a material of each of the first protective layers comprises CuNi.

6. The array substrate according to claim 4, wherein the plurality of pins are connected with the plurality of first protective layers by means of soldering flux, and a material of the soldering flux comprises Sn;
each of the plurality of pads further comprises: a first intermetallic compound layer disposed on a side of the first metal layer facing away from the second metal layer; and
a material of the first intermetallic compound layer comprises CuxSny, wherein x=1 or x=6, and y=3 or y=5.

7. The array substrate according to claim 3, wherein a thickness of each of the first protective layers is greater than or equal to 1 μm.

8. The array substrate according to claim 7, wherein each of the first protective layers comprises a Ni layer and/or a Pd layer;
a thickness of the Ni layer ranges from 1 μm to 10 μm, and a thickness of the Pd layer ranges from 10 nm to 500 nm.

9. The array substrate according to claim 8, wherein each of the first protective layers comprises a Ni layer and an Au layer; the Au layer disposed on a side of the Ni layer facing away from the base substrate, and a thickness of the Au layer ranges from 10 nm to 500 nm.

10. The array substrate according to claim 9, wherein each of the first protective layers further comprises a Pd layer between the Ni layer and the Au layer, and a thickness of the Pd layer ranges from 10 nm to 500 nm.

11. The array substrate according to claim 7, wherein each of the first protective layers comprises a plurality of metal material layers stacked with each other;
each of the metal material layers are made of different materials;
a thickness of each of the metal material layers ranges from 0.1 μm to 10 μm;
a material of each of the metal material layers comprises at least one of gold, vanadium, chromium, copper, and aluminum.

12. The array substrate according to claim 11, wherein each of the first protective layers comprises: a CrCu layer, a Cu layer and an Au layer; and the CrCu layer, the Cu layer and an Au layer are stacked, or
each of the first protective layers comprises an Al layer, a Ni layer and a Cu layer; and the Al layer, the Ni layer and the Cu layer are stacked, or
each of the first protective layers comprises an Al layer, a NiV layer and a Cu layer; and the Al layer, the NiV layer and the Cu layer are stacked, or
each of the first protective layers comprises an Al layer, a V layer and a Cu layer; and the Al layer, the V layer and the Cu layer are stacked.

13. The array substrate according to claim 7, wherein the pins are connected with the first protective layers by means of soldering flux, and a material of the soldering flux comprises Sn;
each of the first protective layers comprises: a first body layer close to the pad, and a second intermetallic compound layer disposed on a side of the first body layer facing away from the base substrate; and
a material of the second intermetallic compound layer comprises MmSnn, wherein M is a metal in the first protective layer.

14. The array substrate according to claim 13, further comprising second protective layers, wherein the second protective layers cover at least part of an area of the pins.

15. The array substrate according to claim 14, wherein each of the second protective layers comprises: a second body layer close to the pin, and a third intermetallic compound layer dispose on a side of the second body layer facing away from the pin; and a material of the third intermetallic compound layer comprises NₐSn_{b}.

16. The array substrate according to claim 14, wherein a material of the second protective layers is same as a material of the first protective layers.

17. The array substrate according to claim 1, further comprising: a first insulating layer between the first conductive layer and the base substrate; and
a second conductive layer between the first insulating layer and the base substrate.

18. The array substrate according to claim 17, wherein the first conductive layer comprises first wires arranged on a same layer as the pads; and
the second conductive layer comprises second wires;
wherein a thickness of each of the first wires is smaller than 2 μm; and a thickness of each of the second wires is smaller than 2 μm.

19. The array substrate according to claim 1, wherein the electronic element is a mini light-emitting diode, LED, a micro LED, or a micro driver chip.

20. An electronic apparatus, comprising the array substrate according to claim 1.
